(19) United States
(12) Patent Application Publication
(10) Pub. No.: US 2025/0336745 A1
(43) Pub. Date: Oct. 30, 2025

(54) SEMICONDUCTOR DEVICES AND METHODS OF MANUFACTURING SEMICONDUCTOR DEVICES

(71) Applicant: Amkor Technology Singapore Holding Pte. Ltd.

(72) Inventors: Wang Gu Lee, Seoul (KR); Kyun Ahn, Gyeonggi-do (KR); In Su Mok, Incheon (KR); Hee Jun Jang, Chungcheongbuk-do (KR); Won Chul Do, Seoul (KR)

(73) Assignee: Amkor Technology Singapore Holding Pte. Ltd., (omitted)

(21) Appl. No.: 18/957,168

(22) Filed: Nov. 22, 2024

Related U.S. Application Data
(60) Provisional application No. 63/638,732, filed on Apr. 25, 2024.

(51) Int. Cl. H01L 23/31; H01L 23/00

(52) U.S. Cl. CPC H01L 23/3171; H01L 24/29; H01L 24/83; H01L 2224/29186; H01L 2224/83896

(57) ABSTRACT

In one example, an electronic device can include an active region comprising a channel region. A first isolation region may be disposed at a lateral side of the channel region. A source region may be located in a footprint of the channel region and disposed between the channel region and the first isolation region. A device passivation can cover a side of the channel region opposite the source region and disposed on a lateral side of the first isolation region. A substrate passivation can be coupled to the device passivation. A bond interface can be disposed between the device passivation and the substrate passivation. A substrate can be coupled to the substrate passivation. Other examples and related methods are also disclosed herein.

### PRIORITY

This application claims priority to U.S. Patent Provisional Application No. 63/638,732 filed on Apr. 25, 2024 and entitled “SEMICONDUCTOR DEVICES AND METHODS OF MANUFACTURING SEMICONDUCTOR DEVICES,” which is incorporated herein by reference.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2G show cross-sectional views of an example method for manufacturing an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of the stated features, but do not preclude the presence or addition of one or more other features.

The terms “first,” “second,” etc. may be used herein to describe various elements, and the elements described using first, second, etc. should not be limited by these terms. The terms “first,” “second,” etc. are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. As used herein, the term “coupled” can refer to an electrical or mechanical coupling.

### DESCRIPTION

An example electronic device can include an active region comprising a channel region. A first isolation region may be disposed at a lateral side of the channel region. A source region may be located in a footprint of the channel region and disposed between the channel region and the first isolation region. A device passivation can cover a side of the channel region opposite the source region and disposed on a lateral side of the first isolation region. A substrate passivation can be coupled to the device passivation. A bond interface can be disposed between the device passivation and the substrate passivation. A substrate can be coupled to the substrate passivation.

An example method of manufacturing an electronic device can include the step of providing a device wafer comprising a front side and a back side. The front side can comprise an active region with an isolation region adjacent a channel region. A first semiconductor material can be removed from the back side of the device wafer to leave an upper side and a lateral side of the isolation region exposed from the channel region. A device passivation can be disposed over the upper side of the isolation region, on the exposed lateral side of the isolation region, and over the channel region. The device passivation can be coupled to a substrate passivation of a substrate wafer. A bond interface can be disposed between the substrate passivation and the device passivation. The substrate wafer can comprise a second semiconductor material coupled to the substrate passivation.

Another example electronic device can include a channel region, an isolation region disposed lateral to the channel region, and a source region disposed between the channel region and the isolation region. A device passivation can be disposed on an upper side of the channel region, on an upper side of the isolation region, and on a first lateral side of the isolation region. A substrate passivation can be coupled to the device passivation by a bond interface between the device passivation and the substrate passivation. A substrate can be coupled to the substrate passivation.

Other examples are included in the present disclosure. Such examples may be found in the figures, in the claims, or in the description of the present disclosure.

Electronic devices of the present disclosure can include a buried oxide layer formed by bonded inorganic oxide layers. Devices can comprise an inorganic passivation on a back side of an electronic component, and another inorganic passivation over a silicon substrate. The inorganic passivation layers can be activated and bonded to one another to make silicon on insulator (SOI) devices with silicon back sides. The techniques to manufacture the electronic devices can be lower cost than traditional techniques and can result in high thermal conductivity to support cooling. Manufacturing techniques described herein tend to reduce saw wear.

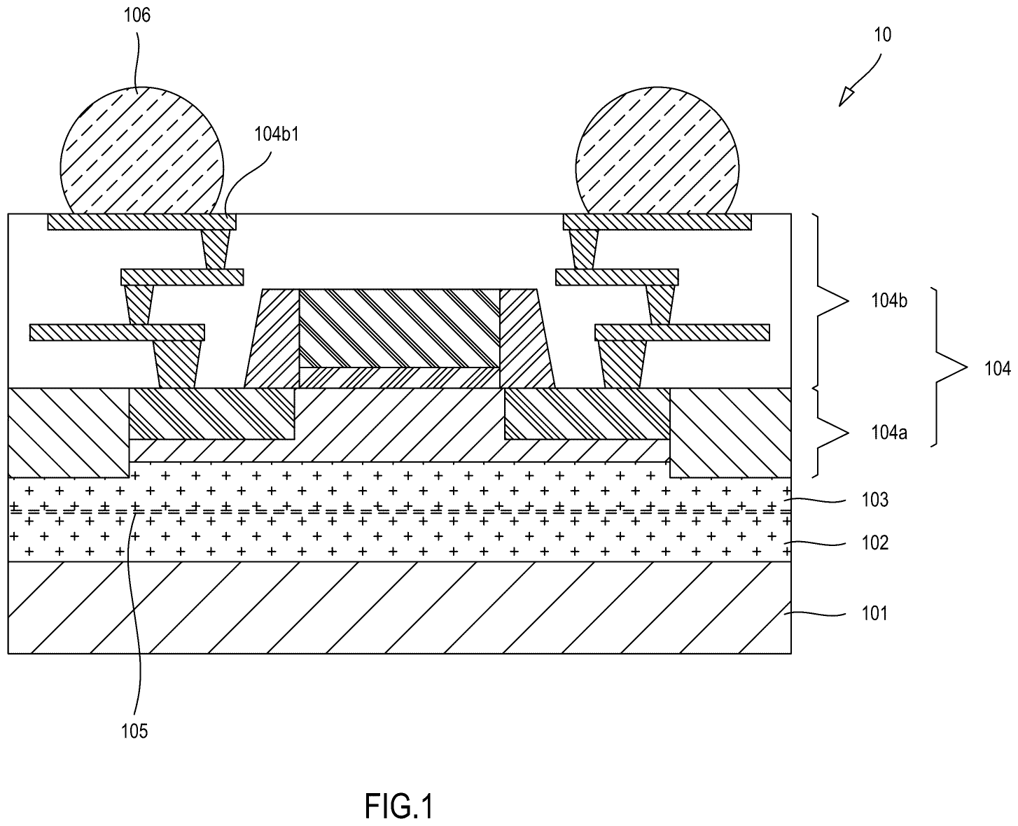

FIG. 1 shows a cross-sectional view of an example electronic device 10. In the example shown in FIG. 1, electronic device 10 can comprise substrate 101, substrate passivation 102, device passivation 103, active region 104, bond interface 105, and external interconnects 106.

Active region or active side 104 can comprise FEOL (Front End Of Line) region 104a and BEOL (Back End Of Line) region 104b. BEOL region 104b can comprise bond pads 104b1. In some examples, BEOL region 104b can also comprise external interconnects 106. FEOL region 104a can protrude into BEOL region 104b in some examples, as shown in the example of FIG. 1.

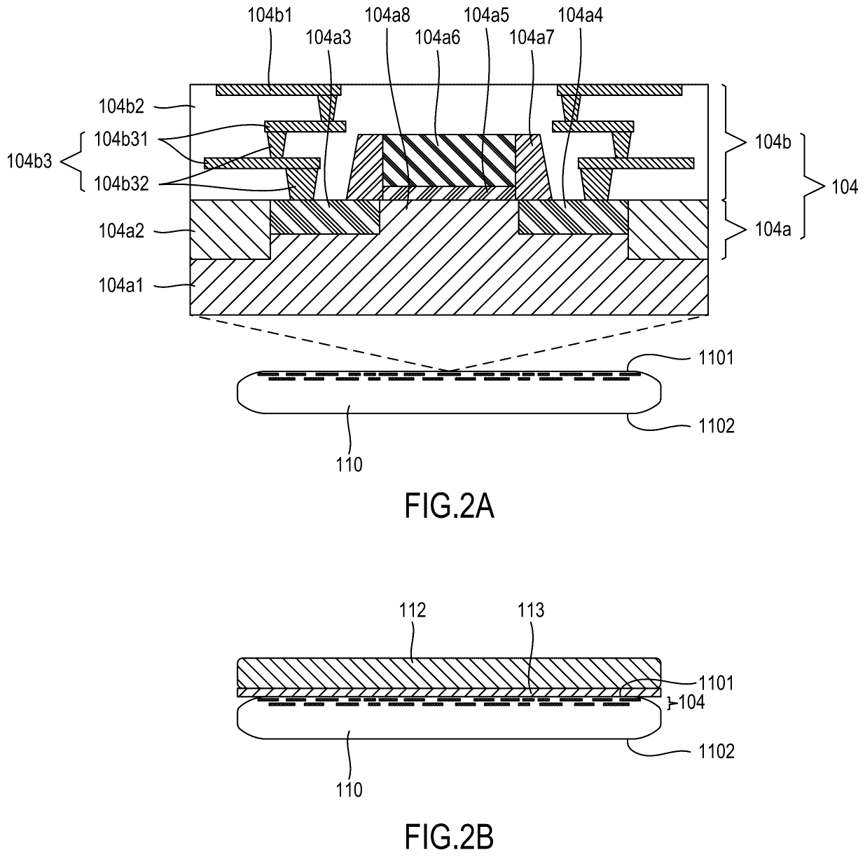

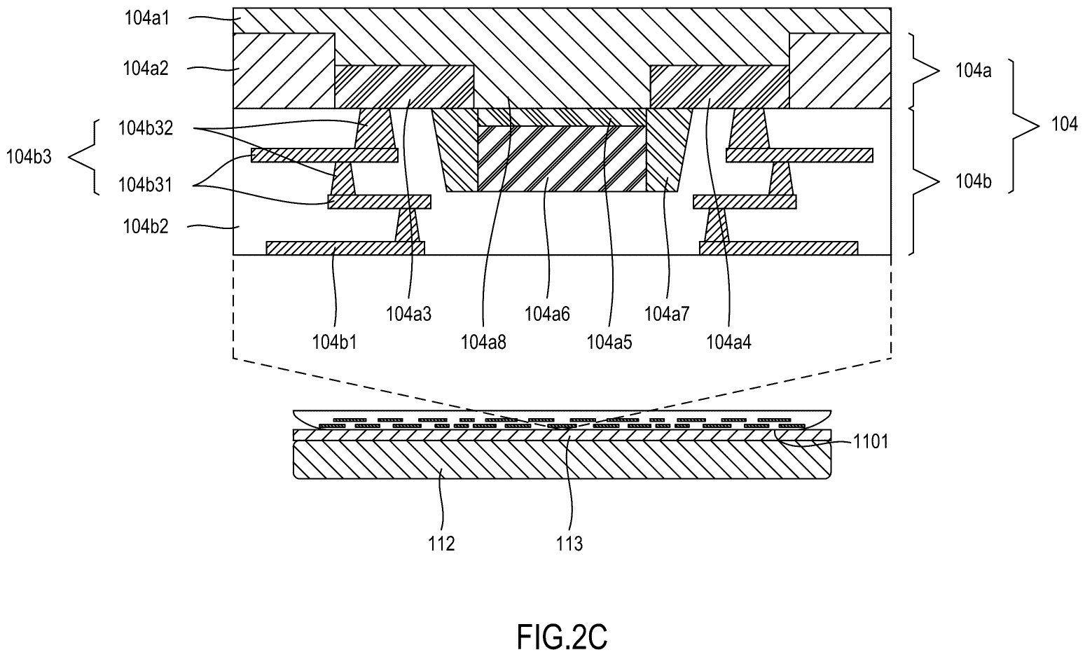

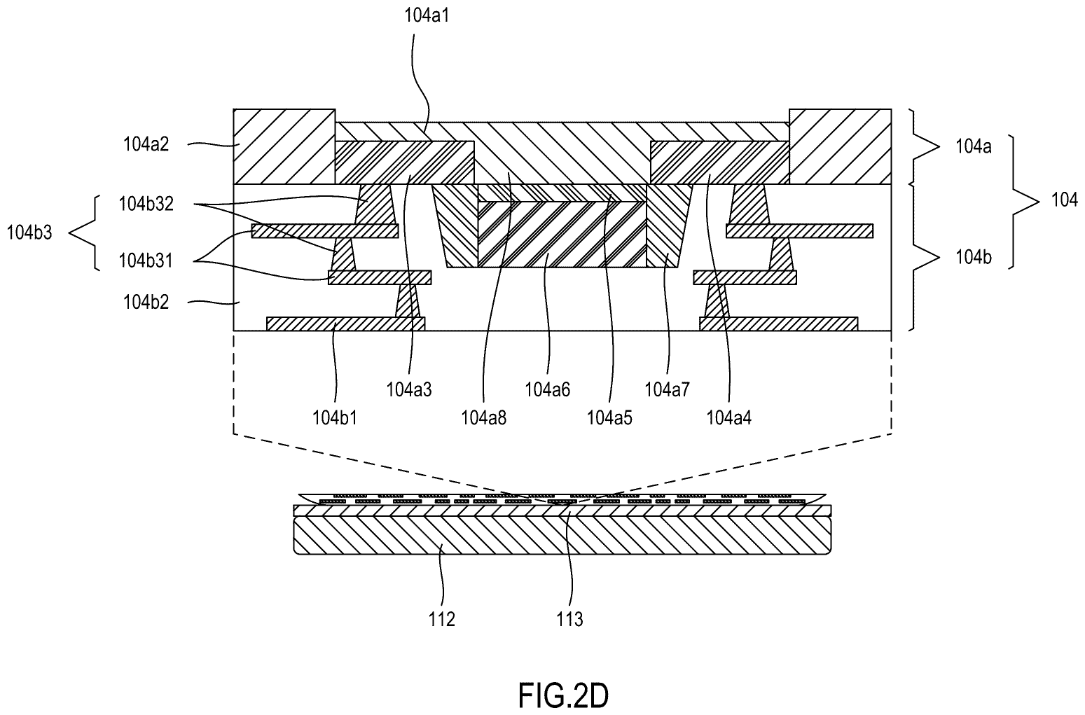

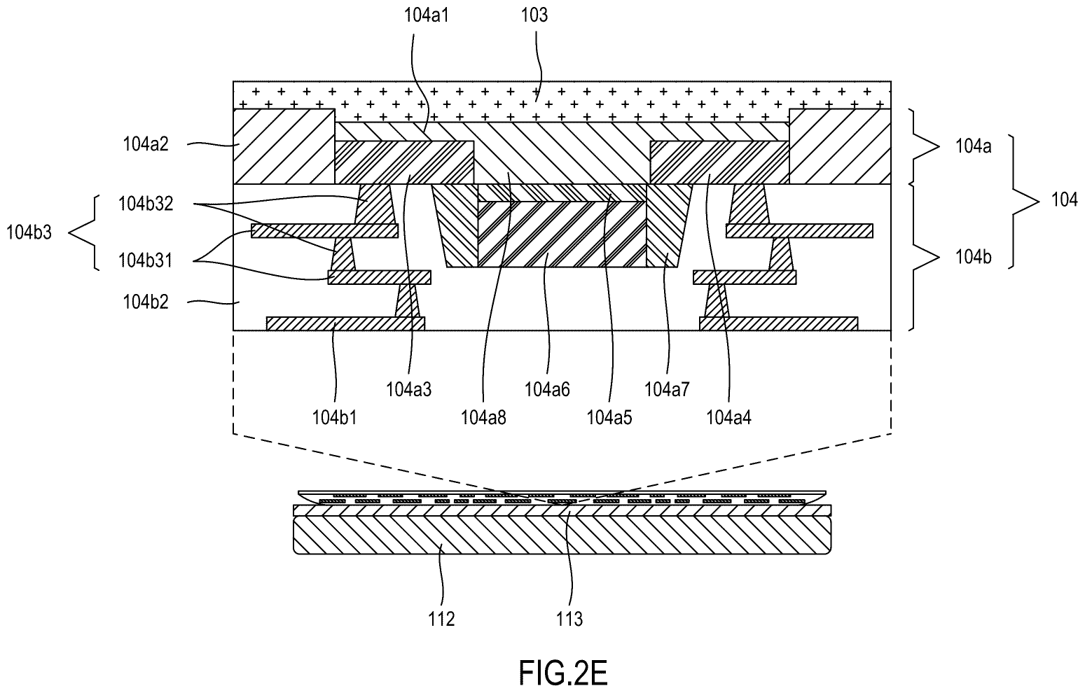

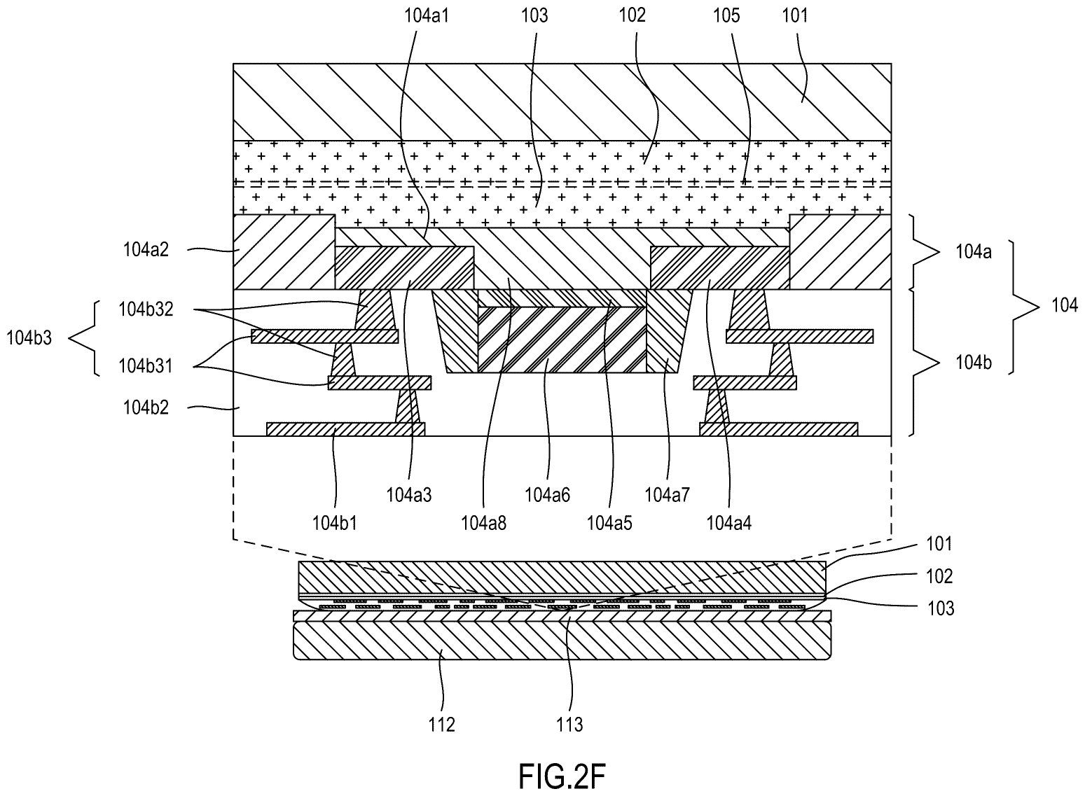

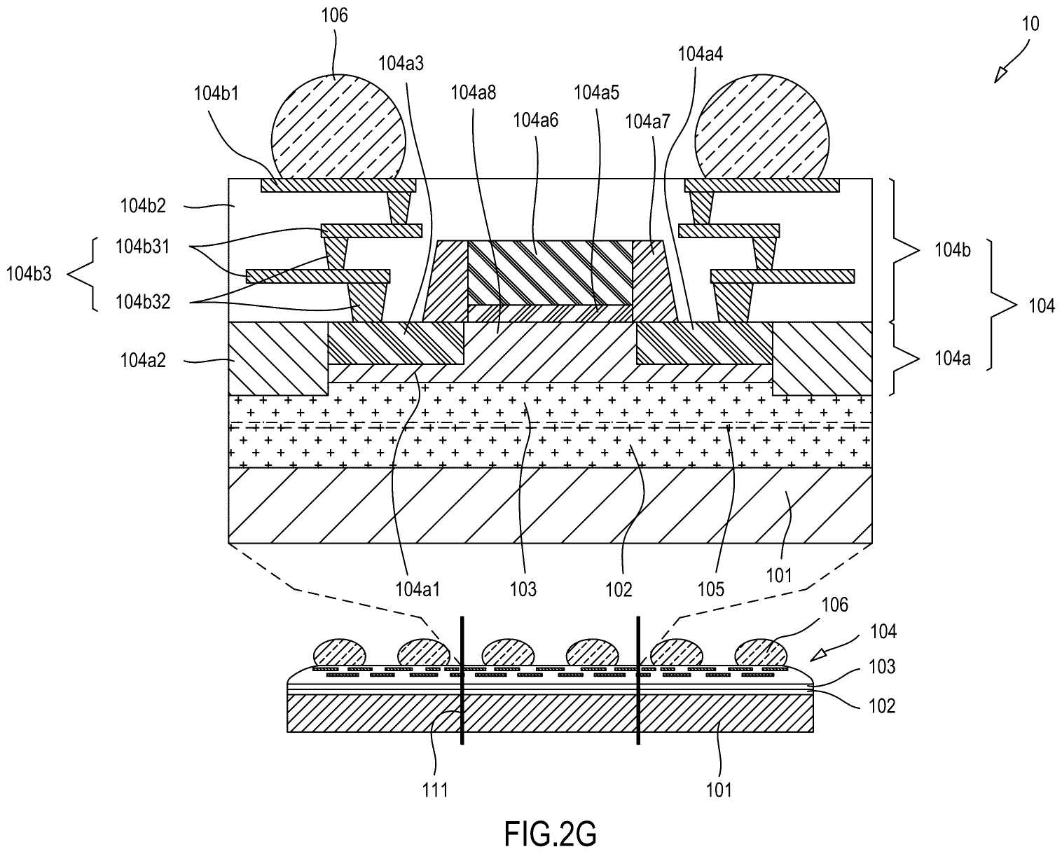

FIGS. 2A to 2G show cross-sectional views of an example method for manufacturing an electronic device, such as electronic device 10 of FIG. 1.

FIG. 2A shows a cross-sectional view of electronic device 10 at an early stage of manufacture. In the example shown in FIG. 2A, device wafer 110 can be provided. Device wafer 110 can comprise a semiconductor material or wafer material, such as, for example, silicon (Si), germanium (Ge), gallium arsenide (GaAs), silicon carbide (SiC), or gallium nitride (GaN). Device wafer 110 can comprise or be referred to as a slice, substrate, single crystal substrate, or crystalline substrate. In some examples, device wafer 110 can be provided through an ingot manufacturing process of making a high-purity semiconductor solution and allowing crystals to grow at high temperature, an ingot slicing process of slicing the ingot to a uniform thickness with a diamond saw, a wafer lapping polishing process of smoothly processing the cut wafer like a mirror, and fabrication (FAB) process of providing an active region 104 on the surface of the wafer through a number of physical or chemical processes. In some examples, the width or diameter of device wafer 110 can range from approximately 50 millimeters (mm) to approximately 300 mm. As used herein with numeric values, the term approximately can mean +/−5%, +/−10%, +/−15%, +/−20%, or +/−25%. In some examples, the width or diameter can be greater than 300 mm. It will be appreciated that the larger the diameter, the more active regions 104 or electronic devices 10 can be included in device wafer 110.

In some examples, the thickness of device wafer 110 can range from approximately 400 micrometers (μm) to approximately 1000 μm, and in some examples the wafer thickness can be reduced to be in the range from approximately 70 μm to approximately 100 μm through a wafer backgrinding process. Device wafer 110 can comprise front side 1101 and backside 1102 opposite front side 1101. Device wafer 110 can comprise multiple active regions 104 including power devices, integrated circuits, or memories provided on front side 1101. In some examples, multiple active regions 104 can be arranged in rows and columns on front side 1101 and can be isolated or otherwise separated from one another by scribe lines or saw streets. In accordance with various examples, each active region 104 can comprise front end of line (FEOL) region 104a and back end of line (BEOL) region 104b.

In some examples, FEOL region 104a can comprise semiconductor body 104a1, isolation region 104a2 (e.g., shallow trench isolation (STI)) provided around semiconductor body 104a1), source region 104a3 and drain region 104a4 provided on semiconductor body 104a1, gate insulating film 104a5 provided between source region 104a3 and drain region 104a4, gate region 104a6 provided on gate insulating film 104a5, and sidewall spacer 104a7 covering lateral sides of gate insulating film 104a5 and gate region 104a6. The region between source region 104a3 and drain region 104a4 in semiconductor body 104a1 can define or be referred to as channel region 104a8. Source region 104a3 and drain region 104a4 in semiconductor body 104a1 can thus be described as in the footprint of channel region 104a8. In some examples, isolation region 104a2, source region 104a3, drain region 104a4, gate insulating film 104a5, gate region 104a6, sidewall spacer 104a7, and channel region 104a8 can comprise or be referred to as a transistor (e.g., a field-effect transistor (FET), a metal-oxide semiconductor field-effect transistor (MOSFET), an insulated gate bipolar transistor (IGBT), a complementary metal-oxide-semiconductor (CMOS), etc.). In some examples, FEOL region 104a can include millions or billions of transistors, capacitors, or resistors.

In accordance with various examples, BEOL region 104b is configured to interconnect the components (e.g., transistors, capacitors, or resistors) of FEOL region 104a. BEOL region 104b comprises dielectric structure 104b2 and conductive structure 104b3. Dielectric structure 104b2 can be provided over FEOL region 104a using physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), printing, lamination, spin coating, spray coating, sintering, thermal oxidation, or any other suitable deposition process. Dielectric structure 104b2 can comprise one or more layers of inorganic dielectric material, such as, SiO2, Si3N4, SiON, SiCN, Ta2O5, or Al2O3.

In various examples, conductive structure 104b3 can be provided within and/or interleaved with layers of dielectric structure 104b2. Conductive structure 104b3 can be formed using PVD, CVD, MOCVD, ALD, LPCVD, PECVD, electrolytic plating, electroless plating process, or any other suitable metal deposition process. In some examples, conductive structure 104b3 can comprise one or more layers of Cu, Al, Au, Ag, Ni, Ti, TiW, Pd, Pt, or other suitable electrically conductive material. In some examples, conductive structure 104b3 can comprise horizontal traces 104b31 and vertical vias 104b32. Conductive structure 104b3 can be electrically connected to source region 104a3, drain region 104a4, or gate region 104a6. Bond pads 104b1 can be provided at the outer side of dielectric structure 104b2 (i.e., at the side opposite FEOL region 104a). Bond pads 104b1 are coupled to conductive structure 104b3. In some examples, bond pads 104b1 and can comprise a source pad electrically connected to source region 104a3, a drain pad electrically connected to drain region 104a4, and a gate pad electrically connected to gate region 104a6. Bond pads 104b1 can be provided using PVD, CVD, MOCVD, ALD, LPCVD, PECVD, electrolytic plating, electroless plating process, or any other suitable metal deposition process. Bond pads 104b1 can comprise Al, Cu, Au, Ag, Ni, Ti, TiW, Pd, Pt, or any other suitable electrically conductive material. In some examples, bond pads 104b1 can comprise under bumped metal (UBM) to improve bonding with external interconnects 106 (FIG. 1). In some examples, a solder resist with openings exposing bond pads 104b1 can be provided on the outer side of dielectric structure 104b2.

FIG. 2B shows a cross-sectional view of electronic device 10 at a later stage of manufacture. In the example shown in FIG. 2B, carrier 112 is provided over device wafer 110. In some examples, carrier 112 can comprise or be referred to as a wafer support system, a wafer, a board, a panel, or a plate. In some examples, carrier 112 can comprise a semiconductor or wafer material, glass, ceramic, or metal. In some examples, carrier 112 can comprise the same material as device wafer 110. The thickness of carrier 112 can range from approximately 300 μm to approximately 2000 μm, and the width, or diameter, of carrier 112 can range from approximately 50 mm to approximately 300 mm. In some examples, the width, or diameter, of carrier 112 can be greater than 300 mm. In some examples, the width, or diameter, of carrier 112 can be similar to or equal to the width or diameter of device wafer 110. Carrier 112 can support device wafer 110 during later processing, as described below.

In some examples, carrier 112 can comprise temporary bond layer 113. Temporary bond layer 113 can be provided on the side of carrier 112 that is oriented toward device wafer 110. Device wafer 110 can be coupled to temporary bond layer 113 of carrier 112. In some examples, temporary bond layer 113 can be provided on device wafer 110, and carrier 112 can be provided over temporary bond layer 113 and device wafer 110. Temporary bond layer 113 can be provided by coating methods, such as doctor blade coating, casting, painting, spray coating, slot die coating, curtain coating, slide coating or knife over edge coating; printing methods, such as screen printing, pad printing or gravure printing; using an intermediate technology between coating and printing, such as flexographic printing, offset printing or inkjet printing; or by directly attaching a adhesive film or adhesive tape to carrier 112.

In some examples, temporary bond layer 113 can comprise or be referred to as a temporary bonding film, a temporary bonding tape, or a temporary adhesive coating. For example, temporary bonding layer 113 can be a heat release tape (or film) or an optical release tape (or film), and the adhesive strength of temporary bonding layer 113 can be weakened or removed by heat or light, respectively. Temporary bond layer 113 can allow carrier 112 to be separated from device wafer 110 (e.g., from front side 1101 of device wafer). In some examples, after front side 1101 of device wafer 110 (i.e., active region 104) can be attached to carrier 112 via temporary bond layer 113, backside 1102 of device wafer 110 can be subjected to backgrinding.

FIG. 2C shows a cross-sectional view of electronic device 10 at a later stage of manufacture. In the example shown in FIG. 2C, a portion of device wafer 110 has been removed from the backside 1102 (FIG. 2B) of device wafer 110.

In accordance with various examples, a backgrinding process can be performed to thin or otherwise remove the portion of device wafer 110. The backside 1102 (FIG. 2B) of device wafer 110 can be thinned to a predetermined thickness by the backgrinding process. The backgrinding process can remove a portion of semiconductor body 104a1. In some examples, the backgrinding process can include grinding device wafer 110 to a first thickness using a polishing pad having relatively large grinding particles and then minutely grinding the backside 1102 (FIG. 2B) of device wafer 110 to a second smaller thickness using a polishing pad having relatively small grinding particles. In some examples, the thickness of device wafer 110 after backgrinding can range from approximately 10 μm to approximately 20 μm. In response to backgrinding, the overall thickness of device wafer 110 and the thickness of the electronic devices 10 formed from device wafer 110 can be reduced.

FIG. 2D shows a cross-sectional view of electronic device 10 at a later stage of manufacture. In the example shown in FIG. 2D, the thickness of device wafer 110 (i.e., the thickness of semiconductor body 104a1) is further reduced.

In accordance with examples, a chemical mechanical polishing (CMP) process can be performed to further reduce the thickness of device wafer 110 (i.e., to remove a portion of semiconductor body 104a1). The CMP process can be applied to semiconductor body 104a1 of device wafer 110. The CMP process can be performed by supplying chemical slurry to a rotating polishing pad and pressing device wafer 110 against the polishing pad. In some examples, the polishing pad and device wafer 110 can rub against each other while rotating in opposite directions. In some examples, the backside of device wafer 110 can be softened by the chemical slurry, and the softened backside can be removed by being ground by mechanical force. In some examples, the CMP polishing speed can be proportional to the product of pressure and speed (relative speed). In some examples, a cleaning process of removing impurities and drying can be performed after the CMP process.

In some examples, the CMP process can remove the backside of device wafer 110 until isolation region 104a2 is exposed. In some examples, the upper side of semiconductor body 104a1 can be lower than the upper side of isolation region 104a2 due to reaction differences from the chemical slurry. A lateral sidewall and an upper wall of isolation regions 104a2 can be exposed from semiconductor body 104a1. In some examples, there can exist a step between the top surface of semiconductor body 104a1 and the top surface of isolation region 104a2 (i.e., semiconductor body 104a1 can be recessed relative to isolation region 104a2, and isolation region 104a2 can protrude from the upper side of semiconductor body 104a2). In some examples, the final remaining thickness of semiconductor body 104a1 can range from approximately 0.145 μm to approximately 0.2 μm. In some examples, the step between the upper side of semiconductor body 104a1 and the upper side of isolation region 104a2 can range from approximately 0.1 μm to approximately 0.2 μm.

FIG. 2E shows a cross-sectional view of electronic device 10 at a later stage of manufacture. In the example shown in FIG. 2E, device passivation 103 can be provided over the backside of device wafer 110.

In accordance with various examples, device passivation 103 can be provided on semiconductor body 104a1 and isolation region 104a2. Device passivation 103 can cover the upper side of semiconductor body 104a1 and the upper side of isolation region 104a2. In some examples, device passivation 103 can contact the upper side of semiconductor body 104a1 and the upper and lateral sides of isolation region 104a2. Device passivation 103 can comprise or be referred to as an insulating material, an inorganic material, a dielectric structure, or an inorganic dielectric structure. In some examples, device passivation 103 can comprise SiO2, Si3N4, SiOxNy (where x and y are natural numbers), or SiCN. In some examples, device passivation 103 can be provided by an oxidation process where oxidation spreads to the inside of device wafer 110 while oxides accumulate on the outside of device wafer 110, or by a deposition process where oxides or nitrides accumulate only on the outside of device wafer 110. In some examples, device passivation 103 can be provided by PVD, CVD, MOCVD, ALD, LPCVD, PECVD, printing, lamination, spin coating, spray coating, sintering, thermal oxidation, or any other suitable deposition process. The thickness of device passivation 103 can range from approximately 500 Ångström (Å) to 3000 Å. As will be discussed again below, this thin device passivation 103 together with a thin substrate passivation 102 and highly thermally conductive substrate 101 can provide excellent thermal conductivity. For example, the thermal conductivity of Si is approximately 149 W/(m·K), the thermal conductivity of Ge is approximately 60 W/(m·K), the thermal conductivity of GaAs is approximately 52 W/(m·K), the thermal conductivity of SiC is approximately 370 W/(m·K), and the thermal conductivity of GaN is approximately 253 W/(m·K). Device passivation 103 and substrate passivation 102 may have thermal conductivity on the order of approximately 1 W/(m·K), though these layers can be thin (e.g., less than approximately 1 μm) in various examples. Device passivation 103 can have lower hardness than an encapsulant containing Al2O3, and thus the amount of wear imparted on a sawing tool used in a later sawing process can be reduced.

FIG. 2F shows a cross-sectional view of electronic device 10 at a later stage of manufacture. In the example shown in FIG. 2F, substrate 101 can be provided over device passivation 103 and device wafer 110.

Substrate 101 can comprise a semiconductor material or wafer material such as Si, Ge, GaAs, SiC, or GaN. Substrate 101 can comprise or be referred to as a slice, a single crystalline substrate, or a crystalline substrate. In some examples, substrate 101 can be provided through an ingot manufacturing process of making a high-purity semiconductor solution and allowing crystals to grow at high temperature, an ingot slicing process of slicing the ingot to a uniform thickness with a diamond saw, and a wafer lapping polishing process of smoothly processing the cut wafer like a mirror. In some examples, substrate 101 can comprise or be referred to as a non-pattern wafer (NPW), a recycled wafer, or a dummy wafer. The size and thickness of substrate 101 can be similar to the initial width or diameter and thickness of device wafer 110. For example, the width or diameter size of substrate 101 can range from approximately 50 mm to approximately 300 mm. The thickness of substrate 101 can range from approximately 400 μm to approximately 1000 μm, and in some examples, through the backgrinding process, the thickness of substrate 101 can be reduced to be in the range from approximately 100 μm to approximately 500 μm. Backgrinding can be performed before or after coupling substrate 101 to device wafer 110.

Substrate 101 can comprise substrate passivation 102. Substrate passivation 102 can be provided on the lower side of substrate 101. Substrate 101 can be disposed over device wafer 110 with substrate passivation 102 oriented toward device wafer 110. Substrate passivation 102 can comprise or be referred to as an insulating material, an inorganic material, a dielectric structure, or an inorganic dielectric structure. In some examples, substrate passivation 102 can comprise SiO2, Si3Np4, SiOxNy (where x and y are natural numbers), or SiCN. In some examples, substrate passivation 102 may be provided by an oxidation process or a deposition process, as described above with reference to device passivation 103. In some examples, substrate passivation 102 can be provided by PVD, CVD, MOCVD, ALD, LPCVD, PECVD, printing, lamination, spin coating, spray coating, sintering, thermal oxidation, or any other suitable deposition process. The thickness of substrate passivation 102 can range from approximately 1000 Angstrom (Å) to approximately 1 μm. As described above, substrate passivation 102 can provide excellent thermal conductivity together with device passivation 103 and substrate 101. The amount of wear imparted on a sawing tool used in the sawing process can be reduced due to a relatively low hardness of substrate 101, substrate passivation 102, and device passivation 103 compared to a molding that contains aluminum filler.

In accordance with various examples, substrate passivation 102 of substrate 101 can then be coupled to device passivation 103, and bond interface 105 can be formed between substrate passivation 102 and device passivation 103. In some examples, a planarization process can be performed on substrate passivation 102 and/or on device passivation 103 prior to bonding. The planarization process can be performed in a manner similar to the CMP process described above. For example, the planarization process can be performed by pressing and rotating substrate passivation 102 or device passivation 103 on a polishing pad while providing chemical slurry on the polishing pad. In some examples, after the planarization process, the average surface roughness (Ra) of substrate passivation 102 and device passivation 103 can range from approximately 1 nanometers (nm) to approximately 100 nm. Maintaining the surface roughness of substrate passivation 102 and device passivation 103 below 100 nm tends to improve bonding the strength at bond interface 105, as decreases in the interaction force between atoms and voids between substrate passivation 102 and device passivation 103 can be reduced or prevented.

In some examples, the bonding process can include applying pressure with substrate passivation 102 contacting device passivation 103. In some examples, a pressure application tool (e.g., a chuck) can apply mechanical pressure to the side of substrate 101 opposite substrate passivation 102 and to the side device wafer 110 opposite device passivation 103, during the bonding process. In some examples, the force applied to substrate passivation 102 and device passivation 103 can range from approximately 1 newton (N) to approximately 1000 N. In some examples, if the force is less than approximately 1 N, the force can be insufficient to sufficiently bond substrate passivation 102 and device passivation 103 to each other, and if the force exceeds approximately 1000 N, substrate 101 or a device can be damaged.

In some examples, an annealing process can further be performed during or after the pressure application process described above. The temperature of the annealing process can range from approximately 300° C. to approximately 400° C. In some examples, if the annealing temperature is below approximately 300° C., substrate passivation 102 and device passivation 103 are not sufficiently bonded to each other, and if the annealing temperature exceeds approximately 400° C., pre-formed active region 104 can be damaged or the characteristics of active region 104 can be changed. In some examples, the annealing temperature can be increased by heating coil or radio frequency (RF). In some examples, the radio frequency can be ultra-high frequency, or millimeter waves, or can comprise a microwave region ranging from approximately 2 GHz to approximately 5 GHz, or a frequency band ranging from approximately 30 MHz to approximately 60 MHz.

In some examples, the annealing process employing heating coil has a duration from approximately 1 hour to approximately 10 hours, while the annealing process by radio frequency can have a duration of approximately 30 seconds to approximately 90 seconds (e.g., rapid annealing). In some examples, rapid annealing can improve bonding strength by inducing covalent bonds before the hydrophilicity of substrate passivation 102 and device passivation 103 is reduced. In some examples, the annealing using radio frequency increases the temperature of only the region participating in bonding, and annealing can be selectively performed by region. Rapid annealing can be advantageous for defect control compared to annealing by hot wire.

In some examples, the bond between device passivation 103 and substrate passivation 102 can initially start as a Van der Waals bond that progresses to a covalent bond through time or temperature. For example, bonding can be achieved between device passivation 103 and substrate passivation 102 through a heat treatment process. For example, bonding between passivation layer 113 and substrate passivation 123 can be achieved at low temperatures through surface activation prior to bonding. For example, by performing surface activation on device passivation 103 and substrate passivation 102, hydrogen (H) can be generated on the surfaces of device passivation 103 and substrate passivation 102 through plasma treatment, oxygen (O) particles separated from water or air during plasma treatment can bind to hydrogen (H) on the surfaces of device passivation 103 and substrate passivation 102, and hydroxyl (OH) groups can be induced on the surfaces of device passivation 103 and substrate passivation 102, respectively. Bonding between device passivation 103 and substrate passivation 102 can be performed at low temperatures. In some examples, device passivation 103 and substrate passivation 102 can be bonded to each other at temperatures ranging from approximately 25° C. to approximately 400° C.

FIG. 2G shows a cross-sectional view of electronic device 10 at a later stage of manufacture. In the example shown in FIG. 2G, external interconnects 106 are provided over bond pads 104b1.

External interconnects 106 can be coupled bond pad 104b1 of BEOL region 104b. External interconnects 106 can be electrically connected to the device region of FEOL region 104a (e.g., source region 104a3, drain region 104a4, or gate region 104a6) through conductive structure 104b3 of BEOL region 104b. In some examples, external interconnects 106 can comprise Sn, Ag, Pb, Cu, Sn—Pb, Sn37-Pb, Sn95-Pb, Sn—Pb—Ag, Sn—Cu, Sn—Ag, Sn—Au, Sn—Bi, or Sn—Ag—Cu. For example, external interconnects 106 can be formed by forming a conductive material containing solder on bond pad 104b1 using a ball drop process and then completed through a reflow process. External interconnects 106 can comprise or be referred to as conductive balls such as solder balls, conductive pillars such as copper pillars, or conductive posts each having a solder cap formed over a copper pillar. In some examples, the sizes or diameters of external interconnects 106 can range from approximately 1 μm to approximately 200 μm. In some examples, external interconnects 106 can be referred to as external input/output terminals of electronic device 10.

After providing external interconnects 106, a singulation process can be performed to separate individual electronic devices 10 by sawing along saw streets 111. During the singulation process, a sawing tool (e.g., diamond blade wheel or laser beam) can cut through active region 104, device passivation 103, substrate passivation 102, and substrate 101 to separate individual electronic devices 10. After singulation, lateral sides of active region 104, device passivation 103, substrate passivation 102, and substrate 101 can be coplanar. In some examples, the hardness of substrate passivation 102 and substrate 101 can be less than the hardness of an encapsulant containing Al2O3 or other metallic fillers. Singulation through substrate passivation 102 and substrate 101 (rather than through an encapsulant including metallic filler) thus tends to reduce the amount of blade wear imparted on the sawing tool. The amount of wear imparted on a sawing tool can thus be reduced by sawing through substrate 101, substrate passivation 102, and device passivation 103 in example electronic devices 10.

In this way, the present disclosure can provide overall low-cost electronic device 10 by using a wafer-to-wafer bonding process, instead of using the previously known and expensive silicon-on-insulation (SOI) process. In some examples, since device passivation 103 and substrate passivation 102 are relatively thin layers, heat from active region 104 can be quickly transferred to substrate 101 and discharged outside. Accordingly, the performance of electronic device 10 tends not to deteriorate in a high temperature environment. Saw wear can be reduced using the techniques described herein, which tends to reduce the overall package manufacturing cost.

The present disclosure includes reference to certain examples, however, it will be understood by those skilled in the art that various changes may be made and equivalents may be substituted without departing from the scope of the disclosure. Modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
an active region comprising a channel region, a first isolation region at a lateral side of the channel region, a source region in a footprint of the channel region and disposed between the channel region and the first isolation region;
a device passivation covering a side of the channel region opposite the source region and disposed on a lateral side of the first isolation region;
a substrate passivation coupled to the device passivation, wherein a bond interface is disposed between the device passivation and the substrate passivation; and
a substrate coupled to the substrate passivation.

2. The electronic device of claim 1, wherein the active region further comprises:
a second isolation region disposed on a second lateral side of the channel region opposite the first lateral side of the channel region; and
a drain region in the footprint of the channel region and disposed between the channel region and the second isolation region.

3. The electronic device of claim 2, wherein the channel region is disposed over the bond interface and between the source region and the drain region.

4. The electronic device of claim 1, wherein the substrate comprises silicon.

5. The electronic device of claim 1, wherein the device passivation extends between the first isolation region and the bond interface.

6. The electronic device of claim 1, wherein an outer side of the first isolation region, an outer side of the device passivation, an outer side of the substrate passivation, and an outer side of the substrate are coplanar in response to singulation.

7. The electronic device of claim 1, wherein the device passivation and the substrate passivation comprise silicon dioxide (SiO2).

8. A method of manufacturing an electronic device, comprising:
providing a device wafer comprising a front side and a back side, wherein the front side comprises an active region including an isolation region adjacent a channel region;
removing a first semiconductor material from the back side of the device wafer to leave an upper side and a lateral side of the isolation region exposed from the channel region;
providing a device passivation over the upper side of the isolation region, on the exposed lateral side of the isolation region, and over the channel region; and
coupling the device passivation to a substrate passivation of a substrate wafer, wherein a bond interface is disposed between the substrate passivation and the device passivation, wherein the substrate wafer comprises a second semiconductor material coupled to the substrate passivation.

9. The method of claim 8, wherein the bond interface starts as a Van der Waals bond and progresses to a covalent bond.

10. The method of claim 8, wherein the channel region is disposed over the bond interface and is between a source region and a drain region of the active region.

11. The method of claim 8, wherein the second semiconductor material of the substrate wafer comprises silicon.

12. The method of claim 8, wherein the device passivation is disposed between the isolation region and the bond interface.

13. The method of claim 8, further comprising cutting through the isolation region, the device passivation, the substrate passivation, and the substrate wafer to singulate the electronic device.

14. The method of claim 8, wherein the device passivation and the substrate passivation comprise silicon dioxide (SiO2).

15. The method of claim 8, wherein coupling the device passivation to the substrate passivation further comprises:
activating a side of the substrate passivation and a side of the device passivation; and
applying heat to bond the side of the substrate passivation to the side of the device passivation.

16. An electronic device, comprising:
a channel region;
an isolation region disposed lateral to the channel region;
a source region disposed between the channel region and the isolation region;
a device passivation disposed on an upper side of the channel region, on an upper side of the isolation region, and on a first lateral side of the isolation region;
a substrate passivation coupled to the device passivation by a bond interface between the device passivation and the substrate passivation; and
a substrate coupled to the substrate passivation.

17. The electronic device of claim 16, further comprising:
a second isolation region disposed on a second lateral side of the channel region opposite the first lateral side; and
a drain region disposed between the channel region and the second isolation region.

18. The electronic device of claim 16, wherein the substrate comprises silicon.

19. The electronic device of claim 16, wherein the device passivation is disposed between the upper side of the isolation region and the bond interface.

20. The electronic device of claim 16, wherein an outer side of the isolation region, an outer side of the device passivation, an outer side of the substrate passivation, and an outer side of the substrate are coplanar in response to singulation.
